(19) United States
(12) Patent Application Publication
(10) Pub. No.: US 2025/0386467 A1
(43) Pub. Date: Dec. 18, 2025

(54) METHODS AND APPARATUS TO COOL COMPONENTS OF SERVERS

(71) Applicant: Intel Corporation, Santa Clara, CA (US)

(72) Inventors: Rahul Hanmant Salunkhe, Bangalore (IN); Yogesh Ramakrishna Kuthkanahalli, Bangalore (IN); Siva Prasad Jangili Ganga, Bangalore (IN); Penchala Pratap Binni Boyina, Bangalore (IN); Murali Macherla, Bangalore (IN)

(73) Assignee: Intel Corporation, Santa Clara, CA (US)

(21) Appl. No.: 19/304,138

(22) Filed: Aug. 19, 2025

(51) Int. Cl. H05K 7/20

(52) U.S. Cl. CPC H05K 7/20809

(57) ABSTRACT

Systems, apparatus, articles of manufacture, and methods to cool components of servers are disclosed. An example heatsink assembly includes a base having a first lateral edge and a second lateral edge opposite the first lateral edge; first fins between the first and second lateral edges of the base, the first fins having a first height defined between first bottom edges and first top edges, the first bottom edges thermally coupled to the base; and second fins coupled to the first fins, the second fins in a region beyond the first lateral edge of the base, the second fins having a second height defined between second bottom edges and second top edges, the second height less than the first height, the second fins closer to the first top edges of the first fins than the second fins are to the first bottom edges of the first fins.

### BACKGROUND

Servers employed in datacenters often include a circuit board carrying one or more integrated circuit (IC) packages (e.g., a processor chip, a system on a chip (SOC)) positioned between banks of memory cards (e.g., dual in-line memory modules (DIMMs)) on either side of the IC packages. The memory cards are often positioned on either side of an IC package in line with a direction of airflow used to cool both the IC package and the memory cards during operation. Often a heatsink assembly is thermally coupled on top of the IC package to facilitate the dissipation of heat generated by the IC package to the cool air being blown across the server.

### BRIEF DESCRIPTION OF THE DRAWINGS

FIG. 1 is a front, top, right partially exploded view of an example server with an example heatsink assembly constructed in accordance with teachings disclosed herein.

FIGS. 2-8 illustrate different views of the example heatsink assembly of FIG. 1.

FIG. 9 is a front, top, right view of the example server of FIG. 1 in a fully assembled state.

FIG. 10 is a side view of the example server of FIG. 1 showing one of the DIMMs being removed.

FIGS. 11-16 illustrate different views of the first and second heat pipes of the example heatsink assembly of FIGS. 1-10 in relationship to the associated heatsink base.

FIGS. 17 and 18 illustrate different views of the heatsink base.

FIGS. 19-26 illustrate different stages in the manufacture and/or assembly of the example heatsink assembly of FIGS. 1-18.

FIG. 27 is a flowchart representative of an example method of manufacturing and/or assembling the example heatsink assembly of FIGS. 1-26.

In general, the same reference numbers will be used throughout the drawing(s) and accompanying written description to refer to the same or like parts. The figures are not necessarily to scale.

### DETAILED DESCRIPTION

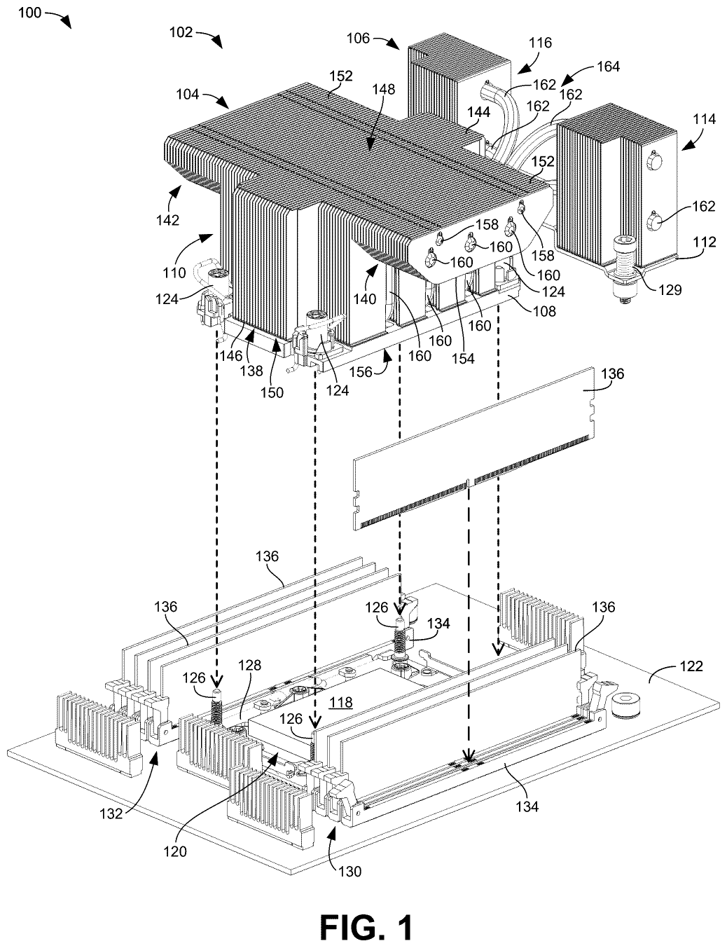

FIG. 1 is a front, top, right partially exploded view of an example server 100 with an example heatsink assembly 102 constructed in accordance with teachings disclosed herein. As shown in the illustrated example, the heatsink assembly 102 includes a main heatsink 104 and an upstream heatsink 106. The main heatsink 104 includes a heatsink base 108 that supports a first array of fins 110. In some examples, the heatsink base 108 is made of copper. However, in other examples, any suitable thermally conductive material can be used. The upstream heatsink 106 includes a bracket 112 (e.g., plate) that supports separate second and third arrays of fins 114, 116. In this example, the heatsink base 108 is to be positioned directly over the top of and thermally coupled to an underlying IC package 118. The IC package 118 is in a socket 120 on a circuit board 122 of the server 100. In some examples, the main heatsink 104 includes one or more fasteners 124 that connect to corresponding posts 126 of a bolster plate 128 associated with and/or surrounding the socket 120. The fasteners 124 ensure the heatsink assembly 102 remains in place and also provide suitable loading on the underlying IC package 118. The example bracket 112 of the heatsink assembly 102 is to be attached (e.g., via fasteners 129) to the circuit board 122 of the server 100 at a location that is upstream of the main heatsink 104 based on the flow path direction of cooling air to be blown across the heatsink assembly 102 (and the associated server 100).

As shown in the illustrated example, the IC package 118 and associated socket 120 (and, thus, the heatsink assembly 102 when attached thereto) are positioned between two separate banks 130, 132 of memory slots 134 structured to receive corresponding dual in-line memory modules (DIMMs) 136 (e.g., memory cards). In the illustrated example, one of the DIMMs 136 is shown removed from a corresponding memory slot 134.

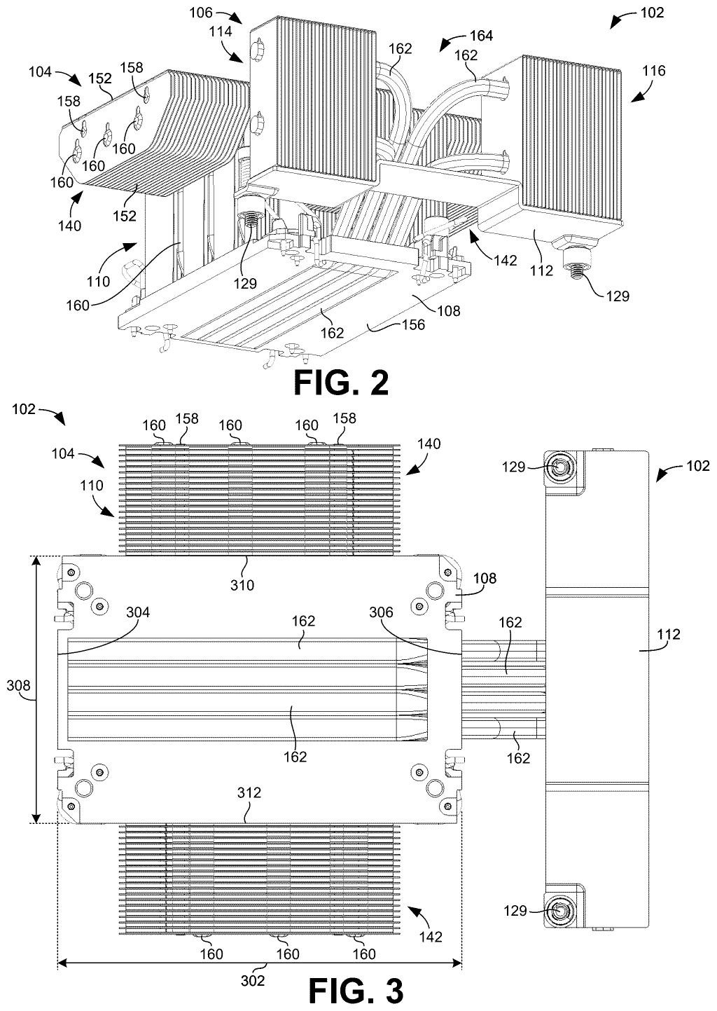

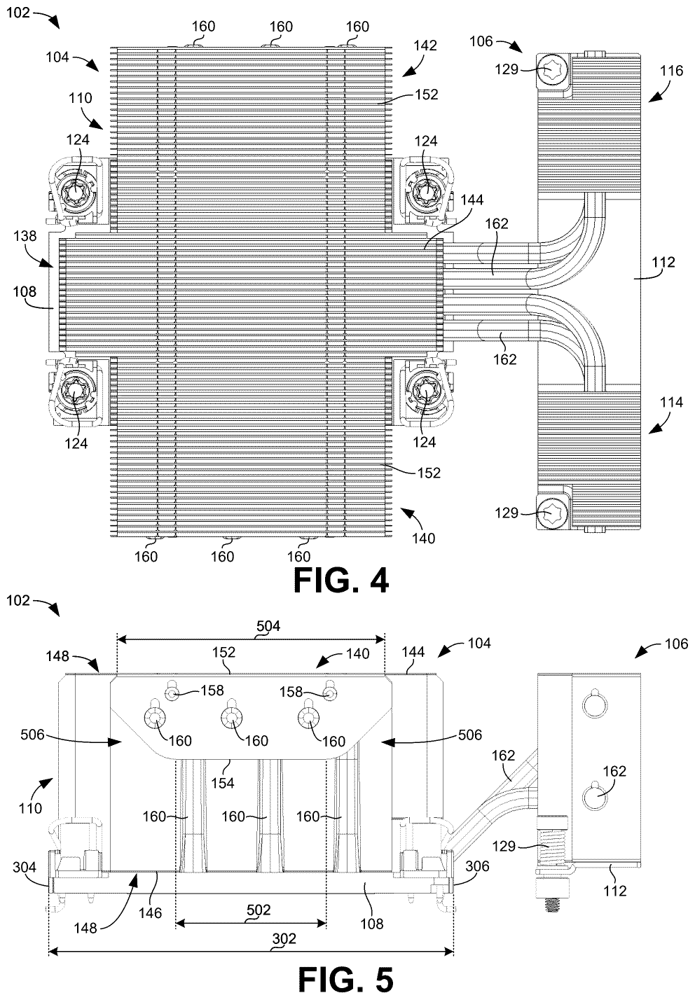

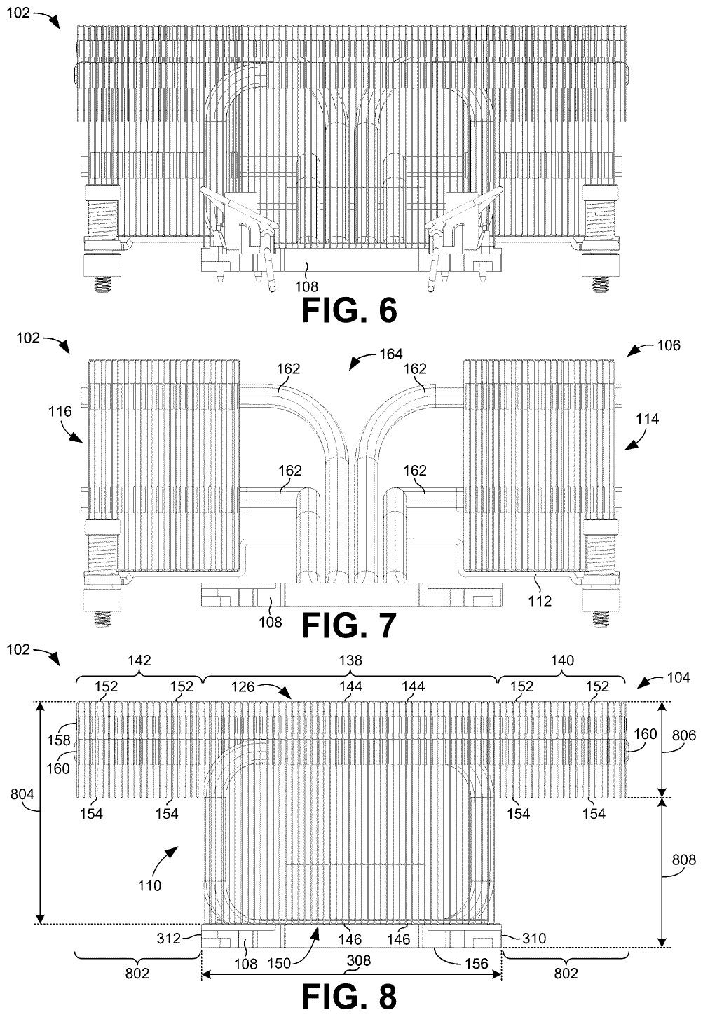

FIGS. 2-8 illustrate different views of the example heatsink assembly 102 that are discussed in connection with FIG. 1. More particularly, FIG. 2 is a rear, bottom, right view of the example heatsink assembly 102. FIG. 3 is a bottom view of the example heatsink assembly 102. FIG. 4 is a top view of the example heatsink assembly 102. FIG. 5 is a right side view of the example heatsink assembly 102. FIG. 6 is a front view of the example heatsink assembly 102. FIG. 7 is a front view of the example heatsink assembly 102 similar to what is shown in FIG. 6 except that the first array of fins 110 (and associated heat pipes and support rods) have been omitted for purposes of illustration. FIG. 8 is a front view of the example heatsink assembly 102 similar to what is shown in FIG. 6 except that the second and third arrays of fins 114, 116 (as well as the bracket 112 and the associated heat pipes) have been omitted for purposes of illustration.

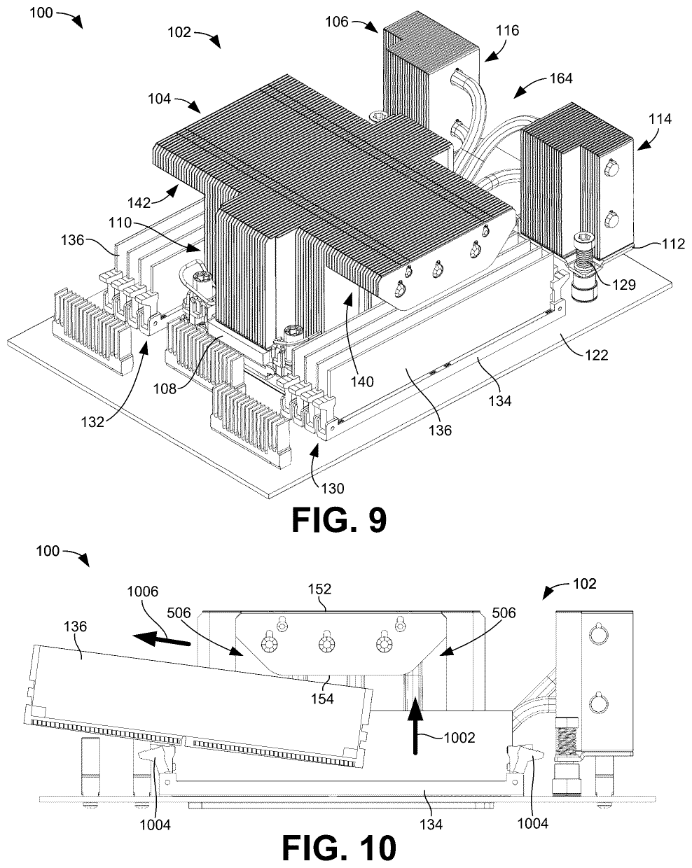

The example heatsink assembly 102 shown in FIGS. 1-8 is constructed for use with a 2 U server. A 2 U server is a server associated with a server chassis that occupies a vertical space of two rack units in a standard server rack (e.g., a vertical space of approximately 3.5 inches). The vertical height of a 2 U server generally extends significantly above upper edges of the DIMMs 136 carried on the circuit board 122 of the server 100. In known 2 U servers, this additional space above the DIMMs results in relatively large volumes of unused space within the chassis. In some known 2 U servers, this open space is filled with air ducting to direct cooling air across and/or through the server. Unlike such known servers, the main heatsink 104 of the example heatsink assembly 102 shown in FIGS. 1-8 is constructed to extend into and/or at least partially fill the open space above the DIMMs 136. More particularly, as shown in the illustrated example of FIGS. 1-8, the first array of fins 110 of the main heatsink 104 includes a central portion 138 and first and second overhang portions 140, 142 (e.g., overhanging portions) on either side of the central portion 138. In this example, the central portion 138 is attached to the heatsink base 108 and the overhang portions 140, 142 extend outward from the central portion 138. As a result, in some examples, whereas the central portion 138 is to be situated between the DIMMs 136 on either side of an associated IC package 118, the overhang portions 140, 142 extend over (e.g., overhang) the DIMMs 136. This is illustrated in the fully assembled view of the example server 100 shown in FIG. 9. Accordingly, in some examples, unlike known 2 U servers, example servers 100 disclosed herein do not include ducting above the DIMMs 136.

In the illustrated example, the implementation of the overhang portions 140, 142 over the DIMMs 136 dissipates more heat than is possible using known 2 U server cooling solutions. For instance, known heatsink assemblies can handle up to 550 W at an ambient air temperature of 25° C. based on typical air flow with a thermal resistance of approximately 0.110 C/W. By contrast, simulations and experimental testing indicate examples disclosed herein can handle a thermal design power (TDP) of more than 700 W with a thermal resistance as low as 0.084 C/W. This corresponds to approximately a 20% improvement in thermal performance. Further, the overhang portions 140, 142 result in the overall heatsink assembly 102 having a larger cross-sectional area than known heatsink solutions. As such, examples disclosed herein offer lower resistance, which enables an increase in air flow. More particularly, known heatsink assemblies are associated with an air flow of approximately 40 cubic feet per minute (CFM), whereas examples disclosed herein enable approximately 60 CFM (e.g., a 50% increase in air flow).

As shown in the illustrated example of FIGS. 1-8, the fins in the central portion 138 of the first array of fins 110 extend substantially parallel to a length 302 of the heatsink base 108 defined between a front (downstream) edge 304 of the heatsink base 108 and a rear (upstream) edge 306 (as labelled in FIGS. 3 and 5). Further, the fins in the central portion 138 are distributed in series across a width 308 of the heatsink base 108 defined between opposing first and second lateral edges 310, 312 (as labelled in FIGS. 3 and 8). As with the central portion 138, the fins in the overhang portions 140, 142 of the first array of fins 110 extend substantially parallel to the length 302 of the heatsink base 108. Thus, in this example, the fins in the overhang portions 140, 142 are substantially parallel to the fins in the central portion 138 of the first array of fins 110. As used herein, substantially parallel means within 5 degrees of exactly parallel. Similarly, as used herein, substantially perpendicular means within 5 degrees of exactly perpendicular. As shown in the illustrated example, the fins in the overhang portions 140, 142 are positioned in (e.g., extend into) regions 802 (labelled in FIG. 8) beyond the lateral edges 310, 312 of the heatsink base 108. Thus, as shown in the illustrated example, the first array of fins 110 is wider than the width 308 of the heatsink base 108.

In some examples, each of the first, second, and third arrays of fins 110, 114, 116 has a similar fin pitch. In some examples, the fin pitch is approximately 1.6 mm. However, in other examples, the fin pitch can be greater or less than 1.6 mm. Further, in some examples, different ones of the arrays of fins 110, 114, 116 are implemented with different fin pitches.

As noted above, the regions 802 beyond the lateral edges 310, 312 into which the overhang portions 140, 142 of the first array of fins 110 extend correspond to the areas where the DIMMs 136 are located in the assembled server 100 shown in FIG. 9. However, the fins in the overhang portions 140, 142 are dimensioned and positioned to be spaced apart from and above the DIMMs 136. Thus, as shown in the illustrated examples, the fins in the overhang portions 140, 142 are smaller than the fins in the central portion 138 of the first array of fins 110. Further, the fins in the overhang portions 140, 142 are spaced apart from and elevated relative to the heatsink base 108.

More particularly, the fins in the central portion 138 of the first array of fins 110 have a first height 804 (labelled in FIG. 8) defined between corresponding top and bottom edges 144, 146. As shown in the illustrated example, the bottom edges 146 of the fins in the central portion 138 are adjacent to and directly coupled (e.g., thermally coupled) to the heatsink base 108. The fins in the central portion 138 extend, from the bottom edges 146, away from the heatsink base 108 towards the top edges 144, which are distal to the heatsink base 108. In this example, the top edges 144 of the fins in the central portion 138 correspond to and/or define a top side 148 of the central portion 138 of the first array of fins 110 and the bottom edges 146 of the fins in the central portion 138 correspond to and/or define a bottom side 150 of the central portion 138.

The fins in the overhang portions 140, 142 of the first array of fins 110 have a second height 806 (labelled in FIG. 8) defined between corresponding top and bottom edges 152, 154. As shown in the illustrated example, the second height 806 is less than the first height 804. In some examples, the second height 906 is significantly less than the first height 804 (e.g., less than half the first height 804). In some examples, the overhang portions 140, 142 are closer to the top side 148 of the central portion 138 than the overhang portions 140, 142 are to the bottom side 150 of the central portion 138. That is, the fins in the overhang portions 140, 142 are closer to the top edges 144 of the fins in the central portion 138 than the fins in the overhang portions 140, 142 are to the bottom edges 146 of the fins in the central portion 138. In some examples (as shown), the top edges 152 of the fins in the overhang portions 140, 142 are aligned with the top edges 144 of the fins in the central portion 138. In other words, in some examples, the top edges 144, 152 of the fins in both the central portion 138 and the overhang portions 140, 142 are at a same elevation (e.g., height) relative to the heatsink base 108. However, in other examples, the top edges 152 of the fins in the overhang portions 140, 142 can be at different elevations from the top edges 144 of the fins in the central portion 138.

In some examples, the height 806 and associated position (e.g., elevation) of the overhang portions 140, 142 relative to the central portions 138 results in a vertical distance 808 (labelled in FIG. 8) between the bottom edges 154 of the associated fins and a bottom surface 156 of the heatsink base 108 that is greater than a height of a DIMM 136. As a result, when the heatsink assembly 102 is installed on the circuit board 122 carrying DIMMs 136 (as shown in FIG. 9), the overhang portions 140, 142 of the first array of fins 110 are above and spaced apart from the DIMMs 136.

As shown in the illustrated example, rods 158 (e.g., support rods, solid metal rods, support pins) extend all or substantially all of the width of the first array of fins 110. That is, in some examples, the rods 158 extend through the central portion 138 as well as through both overhang portions 140, 142. The rods 158 of the illustrated example increase structural integrity to the array of fins 110 to help support the weight of the overhang portions 140, 142. Although two rods 158 are shown, in other examples, more than two rods 158 may be employed. In other examples, only one rod 158 is used. In other examples, the rods 158 are omitted.

In some examples, as shown in FIG. 5, the bottom edges 154 of the fins in the overhang portions 140, 142 have first lengths 502 that are less than second lengths 504 of the top edges 152 of the fins. In some examples, the different lengths 502, 504 of the top and bottom edges 152, 154 of the fins is a result of the shape of the side profile of the fins. More particularly, in some examples, the front (downstream) and rear (upstream) edges of the fins in the overhang portions 140, 142 (e.g., the edges extending between the top and bottom edges 152, 154 of such fins) are angled and/or curved to define open areas 506 (labelled in FIG. 5) at the bottom corners of a rectangle demarcating the side profiles of the fins. In some examples, the open areas 506 are dimensioned to facilitate insertion and/or removal of the DIMMs 136 from the memory slots 134 on the circuit board 122 without needing to remove the heatsink assembly 102 from the circuit board 122. This process is illustrated in FIG. 10, which shows a side view of the server 100 of FIG. 1 with the heatsink assembly 102 attached thereto with the overhang portions 140, 142 extending over the DIMMs 136. As shown in the illustrated example, there is space between the top edges of the DIMMs 136 and the bottom edges 154 of the fins such that the DIMMs 136 can be lifted out of the memory slots 134 as represented by the first arrow 1002. Once free from the memory slots 134, the DIMMs 136 can be rotated and/or angled to extend into the open areas 506, thereby providing enough space to pass over the latches 1004 at each end of the memory slots and remove the DIMMs 136 as represented by the second arrow 1006. Inserting a DIMM 136 into a memory slot 134 can be achieved by reversing the above process.

In the illustrated example, the main heatsink 104 of the heatsink assembly 102 is associated with a set of first heat pipes 160 that help distribute and/or transfer heat from the heatsink base 108 to the first array of fins 110. Further, in this example, the upstream heatsink 106 of the heatsink assembly 102 is associated with a set of second heat pipes 162 that help distribute and/or transfer heat from the heatsink base 108 to the second and third arrays of fins 114, 116. To achieve this heat transfer, in some examples, both sets of heat pipes 160, 162 are in contact with (e.g., attached to, thermally coupled to) the heatsink base 108 and the respective arrays of fins 110, 114, 116. More particularly, in some examples, the first heat pipes 160 extend from the heatsink base 108 up through the central portion 138 of the first array of fins 110 and into and across the overhang portions 140, 142. Further, the second heat pipes extend from the heatsink base 108 towards a gap 164 between the second and third arrays of fins 114, 116 before bending towards and through the second and third arrays of fins 114, 116. In some examples, the gap 164 between the second and third arrays of fins 114, 116 is substantially open (as shown in FIG. 7) and aligned with the central portion 138 of the first array of fins 110 to enable cool air to blow directly on the central portion 138 of the first array of fins 110 without having to pass through the second and third arrays of fins 114, 116 of the upstream heatsink 106.

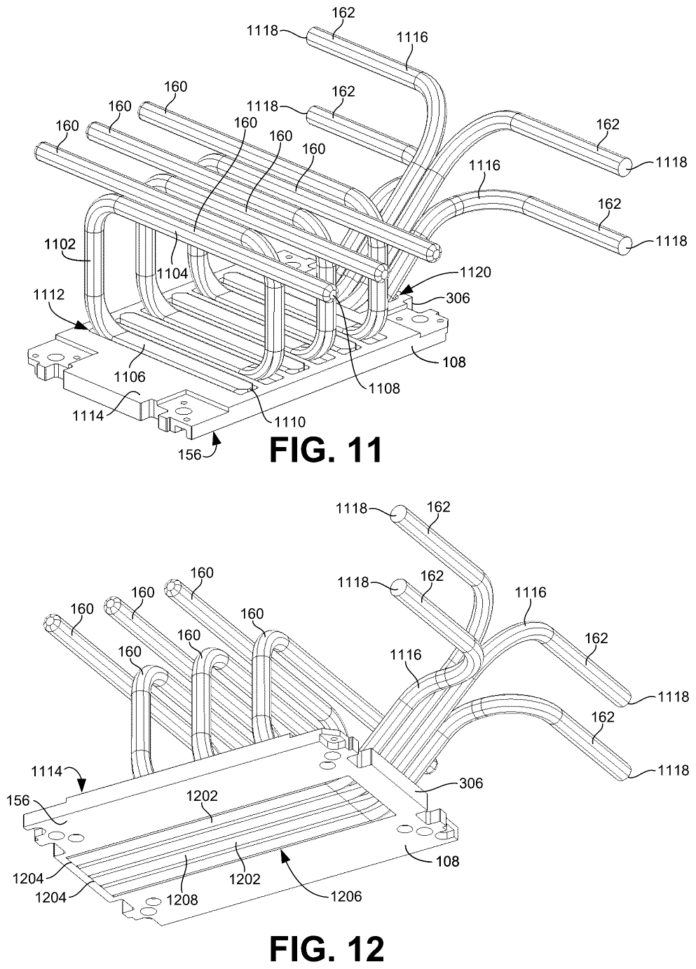

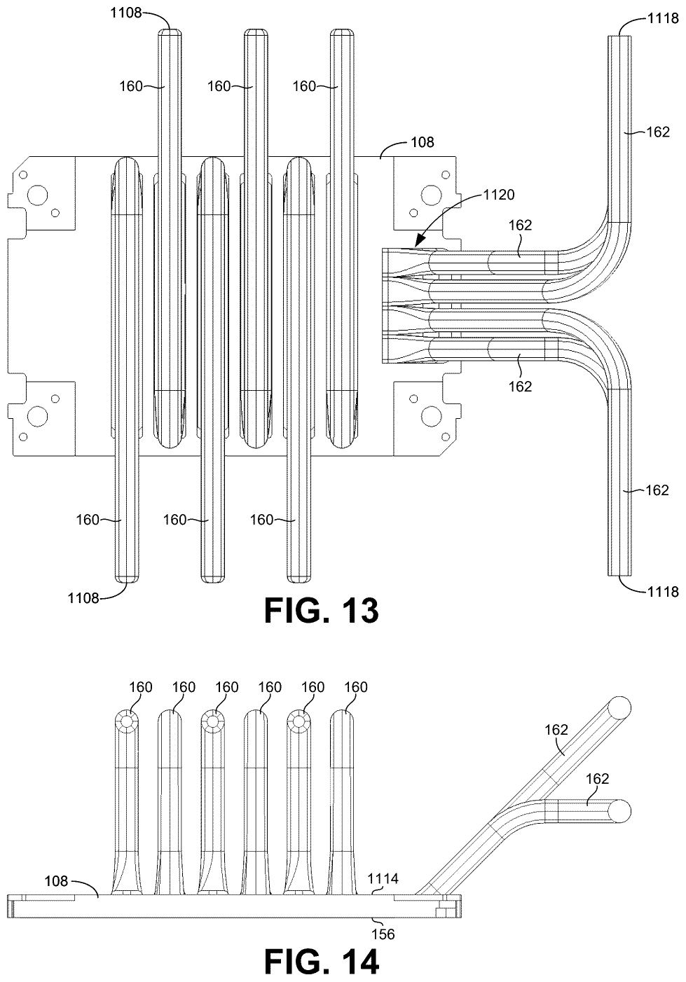

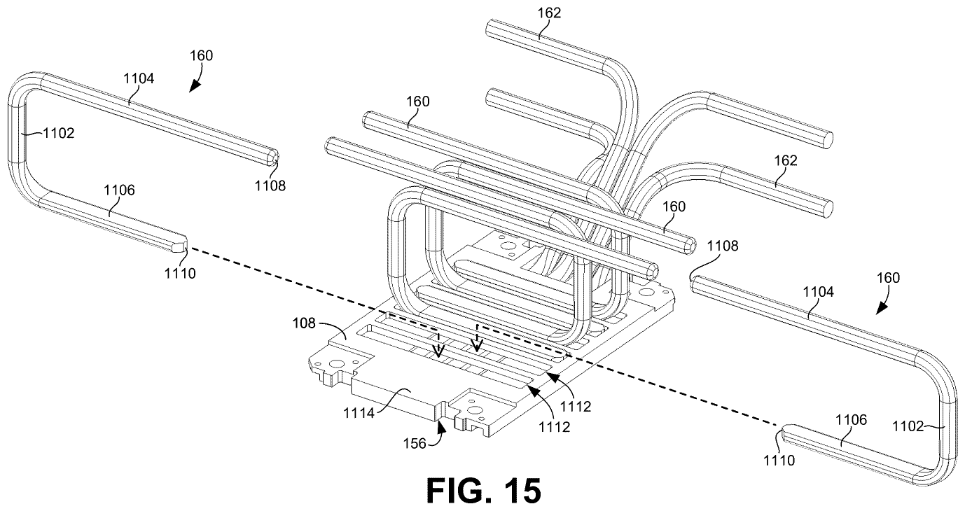

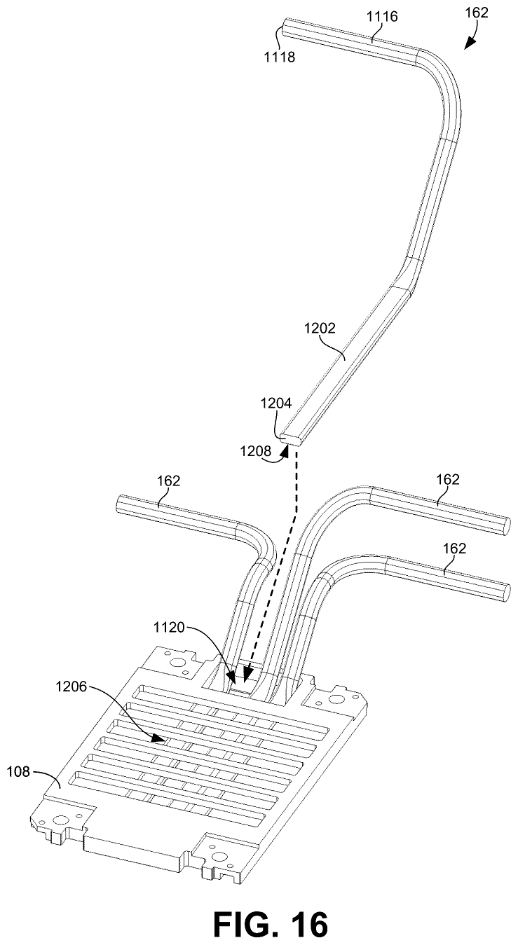

FIGS. 11-16 illustrate different views of the first and second heat pipes 160, 162 in relationship to the heatsink base 108 with all other components removed for purposes of illustration. Specifically, FIG. 11 is a front, top, right view of the example heat pipes 160, 162 and heatsink base 108; FIG. 12 is a rear, bottom, right view of the example heat pipes 160, 162 and heatsink base 108; FIG. 13 is a top view of the example heat pipes 160, 162 and heatsink base 108; FIG. 14 is a right side view of the example heat pipes 160, 162 and heatsink base 108; FIG. 15 is a front, top, right partially exploded view with two of the example first heat pipes 160 spaced apart from the heatsink base 108; and FIG. 16 is a front, top, right partially exploded view with one of the example second heat pipes 162 spaced apart from the heatsink base 108. As shown in the illustrated example, there are six different first heat pipes 160 and four different second heat pipes 162. In other examples, the number of first heat pipes 160 and/or the number of second heat pipes 162 can be different from what is shown.

In the illustrated example, the first heat pipes 160 are U-shaped with a shoulder 1102 (e.g., base, bend, bowl, portion) between opposing first and second stems 1104, 1106 (e.g., arms, legs, segments, portions) at respective first and second ends 1108, 1110 of the first heat pipes 160. In this example, the first heat pipes 160 are oriented in a plane that is transverse (e.g., substantially perpendicular) to the length 302 of the heatsink base 108 and, thus, transverse to the fins in the first array of fins 110. As a result, in this example, the first stem 1104 extends through the first array of fins 110. In some examples, the second stem 1106 extends underneath the array of fins. That is, in some examples, the second stems 1106 of the U-shaped first heat pipes 160 are located between the heatsink base 108 and the bottom edges 146 of the fins in the central portion 138 of the first array of fins 110. In some examples, the first stem 1104 is longer than the second stem 1106 such that the first stem 1104 extends through both the central portion 138 and one of the overhang portions 140, 142. In some examples, the first ends 1108 of the first heat pipes 160 extend up to and/or beyond the outermost fin in the corresponding overhang portion 140, 142. In some examples, the orientation of adjacent ones of the first heat pipes 160 are flipped by 180 degrees such that the first stems 1104 of the adjacent first heat pipes 160 extend into opposing ones of the overhang portions 140, 142.

Whereas the first stem 1104 of each first heat pipe 160 in the illustrated example extends beyond one of the lateral edges 310, 312 of the heatsink base, in some examples, the second stem 1106 of each first heat pipe 160 is directly coupled to (e.g., in contact with, thermally coupled to, embedded within) the heatsink base 108 and confined within the width 308 between the lateral edges 310. In some examples, the second stems 1106 extend substantially (e.g., at least 75% of) the full width 308 of the heatsink base 108. As a result, in some examples, the shoulder 1102 of the U-shaped first heat pipes 160 are proximate one of the lateral edges 310, 312 that is opposite the lateral edge 310, 312 beyond which the first stem 1104 extends.

In some examples, the second stem 1106 of each first heat pipe 160 is within a corresponding trench 1112 (e.g., channel, recess) in a top surface 1114 of the heatsink base 108. In some examples, the different trenches 1112 are connected to define a relatively large, recessed area containing more than one (e.g., all) of the second stems 1106 of the first heat pipes 160. In some examples, the trenches 1112 are omitted such that the first heat pipes 160 are attached to the top surface 1114 of the heatsink base 108. In some examples, the second stem 1106 of the U-shaped first heat pipes 160 is flattened to facilitate thermal coupling between the heat pipes 160 and the heatsink base 108. In other examples, other cross-sectional shapes may be used. In this example, the thickness of the second stems 1106 is greater than the depth of the trenches 1112 such that the second stems 1106 protrude above the top surface 1114 of the heatsink base 108. In other examples, the depth of the trenches 1112 can be equal to or greater than the thickness of the second stems 1106.

In contrast to the first heat pipes 160 that are thermally coupled to a top side (e.g., adjacent the top surface 1114) of the heatsink base 108, the second heat pipes 162 are thermally coupled to a bottom side (e.g., adjacent the bottom surface 156) of the heatsink base 108. More particularly, as shown in FIG. 12, the second heat pipes 162 include first segments 1202 adjacent first ends 1204 of the second heat pipes 162 positioned within a recess 1206 (e.g., trench, channel) in the bottom surface 156 of the heatsink base 108. In this example, the first segments 1202 extend substantially parallel to the length 302 of the heatsink base 108. More particularly, in some examples, the first segments 1202 extend substantially (e.g., at least 75% of) the full length 302 of the heatsink base 108. Thus, in this example, the first segments 1202 of the second heat pipes 162 extend substantially perpendicular to the stems 1104, 1106 of the first heat pipes 160.

In some examples, the first segments 1202 extend within a channel 1206 (e.g., trench, recess) within the bottom surface 156 of the heatsink base 108. In some examples, the first segments 1202 are flattened to facilitate thermally coupling with the heatsink base 108 as well as to facilitate thermally coupling with the IC package 118 to which the heatsink assembly 102 is to be attached. More particularly, in some examples, a bottom surface 1208 of the first segments 1202 of the second heat pipes 162 is substantially flush with the bottom surface 156 of the heatsink base 108 so that both the heatsink base 108 and the second heat pipes 162 can be directly coupled to and/or pressed against the underlying IC package 118. In some such examples, a layer of thermal interface material (TIM) is placed at the interface between the heatsink base 108 (and the second heat pipes 162 extending along the bottom surface 156) and the IC package 118. In some examples, the substantially flush alignment between the bottom surface 1208 of the second heat pipes 162 and the bottom surface 156 of the heatsink base 108 is achieved through a milling, grinding, and/or polishing process after the components have been combined. As used herein, substantially flush means offset by 0.1 mm or less. In some examples, the second heat pipes 162 are flush to within 0.05 mm or less of the heatsink base 108.

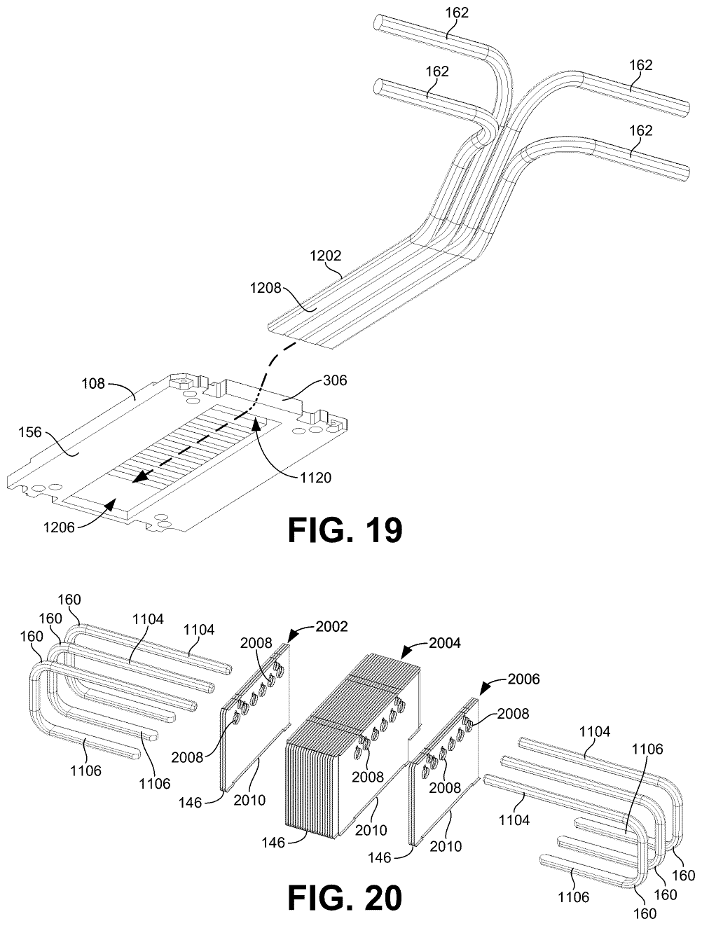

As shown in the illustrated example, while the first segments 1202 of the second heat pipes 162 are positioned underneath the heatsink base 108, second segments 1116 proximate second ends 1118 of the second heat pipes 162 extend above the upper surface 1114 of the heatsink base 108. In this example, the second heat pipes 162 pass through an opening 1120 that extends through the thickness of the heatsink base 108 at a location adjacent the rear edge 306 of the heatsink base 108. In the illustrated example of FIG. 16, one of the second heat pipes 162 is spaced apart from the heatsink base 108 (and the associated opening 1120) while the other second heat pipes 162 have already been inserted through the opening 1120 to be coupled to the heatsink base 108. In some examples, the second heat pipes 162 are connected together before being inserted through the opening 1120 to be positioned within the channel 1206 along the bottom surface 156 of the heatsink base 108 (as shown in FIG. 19 discussed further below). In some examples, the opening 1120 is omitted and the second heat pipes 162 bend around the rear edge 306 of the heatsink base 108. In some such examples, the rear edge 306 of the heatsink base 108 may include a cutout that is similar to the opening 1120 (except that it opens along the rear edge 306) to provide space for the second heat pipes 162 to transition from underneath the heatsink base 108 to extend above the heatsink base 108.

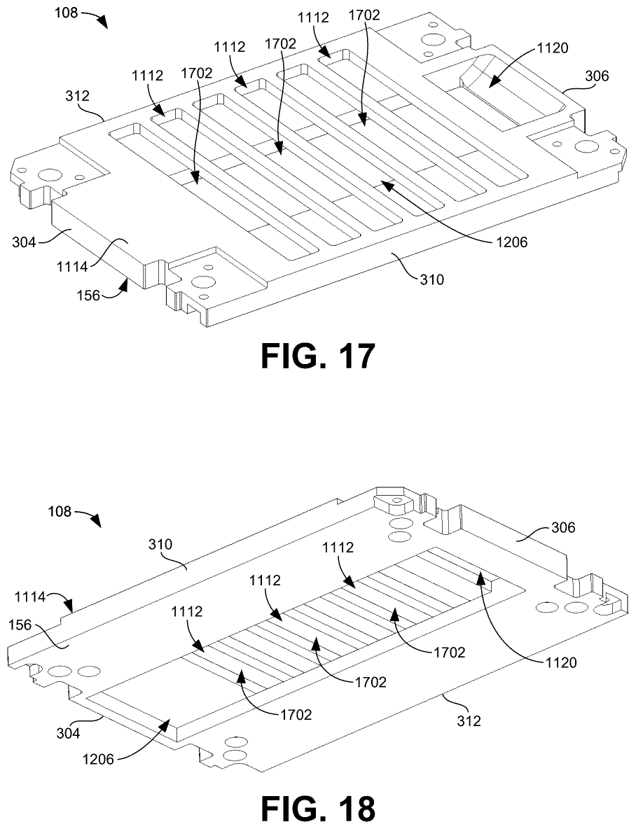

In some examples, the trenches 1112 in the upper surface 1114 of the heatsink base 108 (containing the second stems 1106 of the U-shaped first heat pipes 160) intersect with the channel 1206 in the bottom surface 156 of the heatsink base 108 (containing the first segments 1202 of the second heat pipes). That is, in some examples, the overlapping portions of the trenches 1112 and the channel 1206 connect to define one or more openings 1702 extending through the thickness of the heatsink base 108 as shown in FIGS. 17 and 18, which are views of the heatsink base 108 with all heat pipes removed. In other words, in some examples, the channel 1206 on the bottom surface 156 of the heatsink base 108 is accessible through the trenches 1112 on the upper surface 1114 of the heatsink base 108. Likewise, the trenches 1112 on the upper surface 1114 of the heatsink base 108 are accessible through the channel 1206 on the bottom surface 156 of the heatsink base 108. As a result, in some examples, portions of the first heat pipes 160 (in the trenches 1112) are in direct contact or at least directly thermally coupled to portions of the second heat pipes 162 (in the channel 1206) without any part of the heatsink base 108 therebetween. In other examples, the trenches 1112 and the channel 1206 are not in communication with one another and are separated by a portion of the heatsink base 108 extending therebetween.

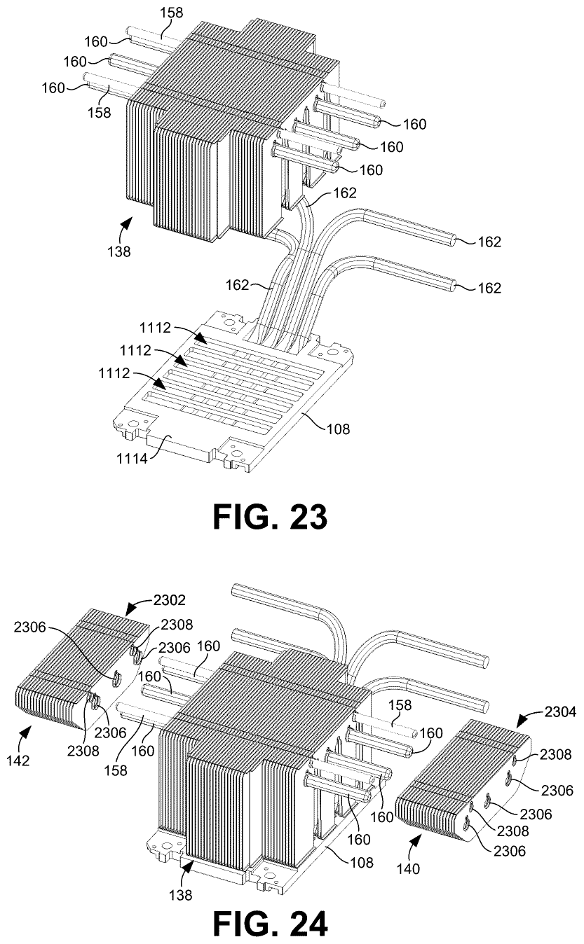

FIGS. 19-26 illustrate different stages in the manufacture and/or assembly of the example heatsink assembly 102 of FIGS. 1-18. In the illustrated example of FIG. 19, the second heat pipes 162 are attached to the heatsink base 108 via a soldering process and/or a welding process. In some examples, as shown, the second heat pipes 162 are already connected together (e.g., via soldering and/or welding) to form a unit that is then inserted through the opening 1120 near the rear edge 306 of the heatsink base 108 to position the first segments 1202 of the second heat pipes 162 within the channel 1206 along the bottom surface 156 of the heatsink base 108. In some examples, once the second heat pipes 162 are positioned within the channel 1206, the bottom surface 156 of the heatsink base 108 and/or the bottom surface 1208 of the first segments 1202 of the heat pipes 162 undergo a grinding and/or milling process to ensure a relatively flat surface (e.g., less than 0.1 mm of variation, less than 0.05 mm of variation) to facilitate an even distribution of pressure across the underlying IC package 118 and reliable thermal coupling with the IC package 118. The resulting assembly after the second heat pipes 162 and the heatsink 108 are combined is shown in FIG. 23.

In the illustrated example of FIG. 20, the U-shaped first heat pipes 160 are provided and attached to three different zipper fin assemblies 2002, 2004, 2006 (e.g., fin array sections) corresponding to different sections of the central portion 138 of the first array of fins 110. In this example, the three different zipper fin assemblies 2002, 2004, 2006 are generally similar except that the middle zipper fin assembly 2004 is wider (includes more fins) and longer than the two outer zipper fin assemblies 2002, 2006. The outer zipper fin assembles 2002, 2006 are shorter than the middle zipper fin assembly 2004 to provide room for the fasteners 124 adjacent each end of the outer zipper fin assemblies 2002, 2004. In this example, each of the zipper fin assemblies 2002, 2004, 2006 includes holes 2008 through which the first (longer) stems 1104 of the first heat pipes extend. Notably, in this example, there are no holes for the second stems 1106 of the first heat pipes 160 because the second stems 1106 are to pass underneath the zipper fin assemblies 2002, 2004, 2006. In this matter, the second stems 1106 of the first heat pipes 160 can be directly thermally coupled to the heatsink base 108 as discussed further below in connection with FIG. 23. In some examples, the bottom edges 146 of the fins include cutouts 2010 (a raised portion) that extends over the portion of the second stems 1106 of the first heat pipes 160 that protrude above the upper surface 1114 of the heatsink base 108. In examples where the second stems 1106 fit entirely within the trenches 1112 so as to be substantially flush with (or below) the upper surface 1114 of the heatsink base 108, the cutouts 2010 may be omitted. In this example, each fin includes a single cutout 2010 that extends across all of the first heat pipes 160. In other examples, multiple discrete cutouts 2010 may be provided to extend over individual ones (or separate groupings) of the first heat pipes 160.

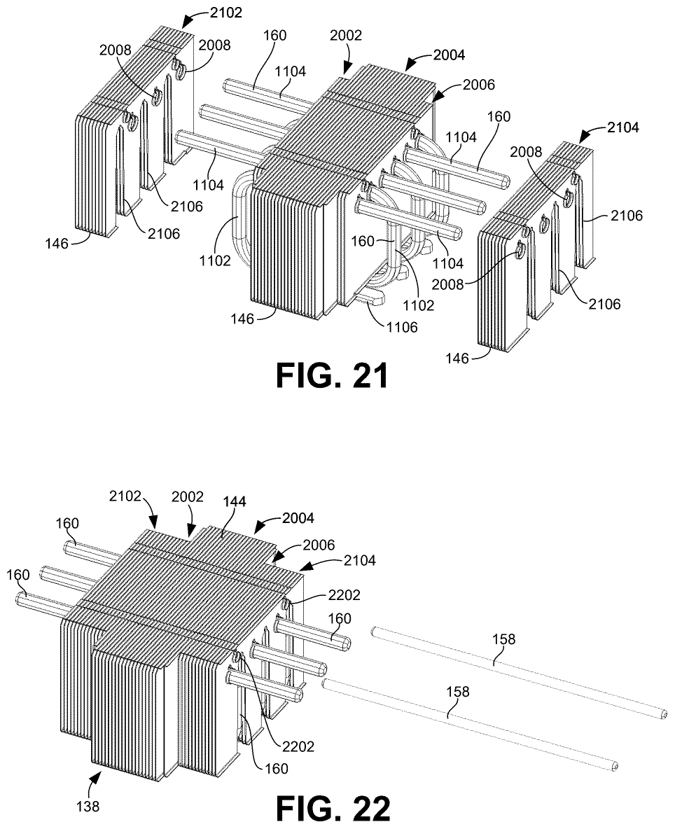

In some examples, once the first heat pipes 160 have been inserted through the holes of the zipper fin assemblies 2002, 2004, 2006, the components are rigidly affixed together via a soldering process and/or a welding process. In some examples, the soldering and/or welding process is performed as the components are being combined together. The resulting assembly after the components are combined is shown in FIG. 21.

In the illustrated example of FIG. 21, additionally zipper fin assemblies 2102, 2104 (e.g., fin array sections) are attached to either side of the first three zipper fin assemblies 2002, 2004, 2006. These additional zipper fin assemblies 2102, 2104 include the outermost fins of the central portion 138 of the first array of fins 110. That is, the five zipper fin assemblies 2002, 2004, 2006, 2102, 2104 shown in FIG. 21 correspond to the complete central portion 138. As shown in the illustrated example, the additional zipper fin assemblies 2102, 2104 have a similar length to the outer zipper fin assemblies 2002, 2006, but are wider (e.g., include more fins) than the outer zipper fin assemblies 2002, 2006.

The additional zipper fin assemblies 2102, 2104 also differ from the outer zipper fin assemblies 2002, 2006 in the nature of the holes included therein. More particularly, as shown in the illustrated example, the additional zipper fin assemblies 2102, 2104 include similar holes 2008 to receive the ends of the first stems 1104 pointing towards the respective additional zipper fin assembles 2102, 2104. However, instead of holes 2008 for the first heat pipes 160 with first stems 1104 pointing away from the respective zipper fin assembles 2102, 2104, the additional zipper fin assembles 2102, 2104 include elongate vertical slots 2106 that extend from a same height as the holes 2008 all the way down to the bottom edge 146 of the fins. In this example, the slots 2106 provide space for the shoulders 1102 of the first heat pipes 160 that extend between the respective first and second stems 1104, 1106. Thus, as shown in the illustrated example, the additional zipper fin assembles 2102, 2104 include holes 2008 with perimeters that extend all the way around the first stems 1104 such that part of the additional zipper fin assemblies 2102, 2104 is between the first and second stems 1104, 1106. By contrast, the slots 2106 extend from the respective first stems 1104 to the bottom edges 146 of the fins such that there is an open space between the respective first and second stems 1104, 1106 of the first heat pipes 160.

In some examples, once the additional zipper fin assembles 2102, 2104 have been positioned over top of and/or around the first heat pipes 160 and adjacent the outer zipper fin assemblies 2002, 2006, the components are rigidly affixed together via a soldering process and/or a welding process. In some examples, the soldering and/or welding process is performed as the components are being combined together. The resulting assembly after the components are combined is shown in FIG. 22.

In the illustrated example of FIG. 22, the rods 158 extend through the central portion 138 of the first array of fins 110 (including all five zipper fin assemblies 2002, 2004, 2006, 2102, 2104 discussed above). More particularly, as shown in the illustrated example, the rods 158 extend through additional holes 2202 in the fins. In this example, the additional holes 2202 are located close to the top edges 146 of the fins so that the supports rods 158 protrude outward from the central portion 138 at a height aligned with the overhang portions 140, 142. In this manner, the rods 158 provide mechanical support to the overhang portions 140, 142. In some examples, once the rods 158 have been inserted through the holes 2202 in the fins, the components are rigidly affixed together via a soldering process and/or a welding process. In some examples, the soldering and/or welding process is performed as the rods 158 are being inserted in the array of fins. The resulting assembly after the components are combined is shown in FIG. 23.

In the illustrated example of FIG. 23, the central portion 138 of the first array of fins 110 (along with the first heat pipes 160 and supporting rods 158 attached thereto) is attached to the heatsink base 108 (to which the second heat pipes 162 have already been attached as noted above in connection with FIG. 19). In some examples, the second stems 1106, which extend underneath the fins of the central portion 138 (and, thus, are not visible in FIG. 23) are positioned within the trenches 1112 in the upper surface 1114 of the heatsink base 108. In some examples, the first heat pipes 160 and/or the fins of the central portion 138 are rigidly affixed to the heatsink base 108 via a soldering process and/or a welding process. The resulting assembly after the components are combined is shown in FIG. 24.

In the illustrated example of FIG. 24, overhanging zipper fan assemblies 2302, 2304 are attached to the central portion 138 of the first array of fins 110. In this example, the overhanging zipper fan assemblies 2302, 2304 correspond to the overhang portions 140, 142 of the first array of fins 110. As shown in the illustrated example, the overhanging zipper fan assemblies 2302, 2304 include first holes 2306 positioned to fit around the first stems 1104 of the first heat pipes 160. Further, the overhanging zipper fan assemblies 2302, 2304 include second holes 2308 positioned to fit around the rods 158. In some examples, once the overhanging zipper fan assemblies 2302, 2304 have been positioned adjacent the outer zipper fin assemblies 2002, 2006 with the first heat pipes 160 and the rods 158 extending therethrough, the components are rigidly affixed together via a soldering process and/or a welding process. In some examples, the soldering and/or welding process is performed as the components are being combined together. The resulting assembly corresponds to the completed first array of fins 110 as shown in FIGS. 1-10 and 25.

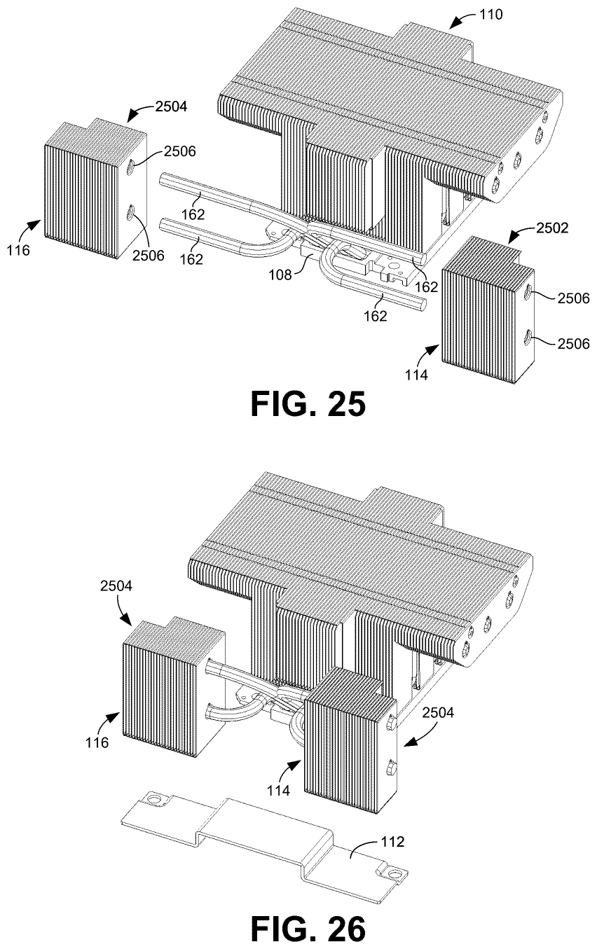

FIG. 25 shows the heatsink base 108, the first array of fins 110, and the associated heat pipes 160, 162 and rods 158 rotated approximately 180 degrees relative to what is shown in FIG. 24. In the illustrated example of FIG. 25, upstream zipper fin assemblies 2502, 2504 are shown being attached to the exposed ends of the second heat pipes 162. In this example, the upstream zipper fin assemblies 2502, 2504 correspond to the second and third arrays of fins 114, 116 of the upstream heatsink 106. As shown in the illustrated example, the upstream zipper fin assemblies 2502, 2504 include holes 2506 positioned to fit around the ends of the second heat pipes 162. In some examples, once the upstream zipper fin assemblies 2502, 2504 have been positioned on the second heat pipes 162, the components are rigidly affixed together via a soldering process and/or a welding process. In some examples, the soldering and/or welding process is performed as the components are being combined together. The resulting assembly after the components are combined is shown in FIG. 26.

In the illustrated example of FIG. 26, the bracket 112 is attached to the underside of the upstream zipper fin assemblies 2502, 2504 (e.g., the second and third arrays of fins 114, 116). In some examples, the bracket 112 is attached to the upstream zipper fin assemblies 2502, 2504 via a soldering process and/or a welding process. In some examples, after the bracket 112 has been attached, the fasteners 124, 129 are added to the respective heatsink base 108 and bracket 112 to complete the construction of the example heatsink assembly 102 of FIGS. 1-10.

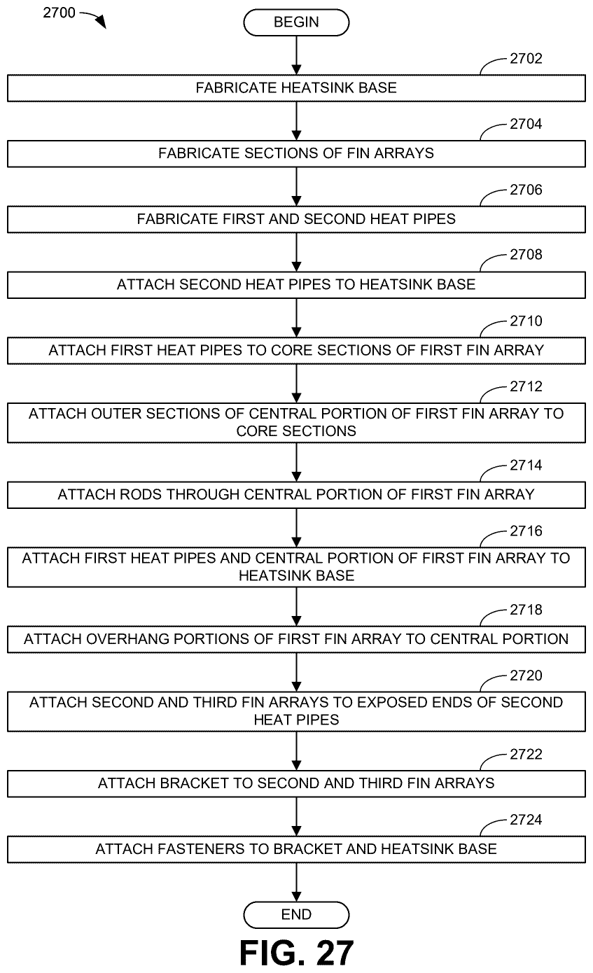

FIG. 27 is a flowchart representative of an example method 2700 of manufacturing and/or assembling the example heatsink assembly of FIGS. 1-26. In some examples, some or all of the operations outlined in the example method of FIG. 27 are performed automatically by fabrication equipment that is programmed to perform the operations. Although the example method of manufacturing is described with reference to the flowchart illustrated in FIG. 27, many other methods may alternatively be used. For example, the order of execution of the blocks may be changed, and/or some of the blocks described may be combined, divided, re-arranged, omitted, eliminated, and/or implemented in any other way. Further, in some examples, additional processing operations can be performed before, between, and/or after any of the blocks represented in the illustrated example.

The example method 2700 begins at block 2702 by fabricating a heatsink base 108. In some examples, the heatsink base 108 is fabricated with trench(es) and/or channel(s) into which ends of the heat pipes are to be located. At block 2704, the example method involves fabricating sections of fin arrays (e.g., the middle zipper fin assembly 2004, the outer zipper fin assemblies 2002, 2006, the additional zipper fin assemblies 2102, 2104, the overhanging zipper fin assemblies 2302, 2304, and the upstream zipper fin assemblies 2502, 2504). At block 2706, the example method involves fabricating the heat pipes (e.g., the first and second heat pipes 160, 162). In some examples, the heat pipes 160, 162 are suitably shaped as shown in FIGS. 11-16 to facilitate attachment to the heatsink base 108 and the fin arrays. Each of blocks 2702-2706 can be performed independent of and/or in parallel with one another. As such, blocks 2702-2706 can be performed in any order.

At block 2708, the example method involves attaching the second heat pipes 162 to the heatsink base 108. This is represented in FIG. 19 as discussed above. In some examples, the second heat pipes 162 and/or the heatsink base 108 undergo a grinding and/or milling process to ensure their bottom surfaces are substantially flush and the underside of the heatsink (as well as the associated first segments 1202 of the heat pipes 162) is substantially flat. At block 2710, the example method involves attaching the first heat pipes 160 to core sections of the first fin array (e.g., the middle zipper fin assembly 2004 and the outer zipper fin assemblies 2002, 2006). This is represented in FIG. 20 as discussed above. At block 2712, the example method involves attaching outer sections (e.g., the outer zipper fin assemblies 2302, 2304) of the central portion 138 of the first fin array to the core sections. This is represented in FIG. 21 as discussed above. At block 2714, the example method involves attaching rods 158 through the central portion 138 of the first fin array. This is represented in FIG. 22 as discussed above. Blocks 2710-2714 can be implemented independent of and/or in parallel with block 2708. Accordingly, in some examples, block 2708 is implemented during or after the implementation of any of blocks 2710-2714.

At block 2716, the example method involves attaching the first heat pipes 160 and the central portion 138 of the first fin array to the heatsink base 108. This is represented in FIG. 23 as discussed above. At block 2718, the example method involves attaching the overhang portions 140, 142 (e.g., the additional zipper fin assemblies 2102, 2104) of the first fin array to the central portion 138. This is represented in FIG. 24 as discussed above. In some examples, block 2718 is implemented before block 2716.

At block 2720, the example method involves attaching second and third fin arrays (e.g., the upstream zipper fin assemblies 2502, 2504) to the exposed ends of the second heat pipes 162. This is represented in FIG. 25 as discussed above. At block 2722, the example method involves attaching the bracket 112 to the second and third fin arrays. This is represented in FIG. 26 as discussed above. Blocks 2720 and 2722 can be implemented independent of and/or in parallel with blocks 2710-2718. Thus, in some examples, blocks 2720 and 2722 can be implemented before some or all of blocks 2710-2718.

At block 2724, the example method involves attaching fasteners 124, 129 to the bracket 112 and the heatsink base 108. At this point, the heatsink assembly 102 is complete and the example method 2700 of FIG. 27 ends.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities, etc., the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities, etc., the phrase “at least one of A or B” is intended to refer to implementations including any of (1) at least one A, (2) at least one B, or (3) at least one A and at least one B.

As used herein, singular references (e.g., “a”, “an”, “first”, “second”, etc.) do not exclude a plurality. The term “a” or “an” object, as used herein, refers to one or more of that object. The terms “a” (or “an”), “one or more”, and “at least one” are used interchangeably herein. Furthermore, although individually listed, a plurality of means, elements, or actions may be implemented by, e.g., the same entity or object. Additionally, although individual features may be included in different examples or claims, these may possibly be combined, and the inclusion in different examples or claims does not imply that a combination of features is not feasible and/or advantageous.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly within the context of the discussion (e.g., within a claim) in which the elements might, for example, otherwise share a same name.

As used herein, “approximately” and “about” modify their subjects/values to recognize the potential presence of variations that occur in real world applications. For example, “approximately” and “about” may modify dimensions that may not be exact due to manufacturing tolerances and/or other real world imperfections as will be understood by persons of ordinary skill in the art. For example, “approximately” and “about” may indicate such dimensions may be within a tolerance range of +/−10% unless otherwise specified herein.

As used herein “substantially real time” refers to occurrence in a near instantaneous manner recognizing there may be real world delays for computing time, transmission, etc. Thus, unless otherwise specified, “substantially real time” refers to real time+1 second.

As used herein, the phrase “in communication,” including variations thereof, encompasses direct communication and/or indirect communication through one or more intermediary components, and does not require direct physical (e.g., wired) communication and/or constant communication, but rather additionally includes selective communication at periodic intervals, scheduled intervals, aperiodic intervals, and/or one-time events.

As used herein, “programmable circuitry” is defined to include (i) one or more special purpose electrical circuits (e.g., an application specific circuit (ASIC)) structured to perform specific operation(s) and including one or more semiconductor-based logic devices (e.g., electrical hardware implemented by one or more transistors), and/or (ii) one or more general purpose semiconductor-based electrical circuits programmable with instructions to perform specific functions(s) and/or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations and/or functions, Field Programmable Gate Arrays (FPGAs) that may be programmed with second instructions to cause configuration and/or structuring of the FPGAs to instantiate one or more operations and/or functions corresponding to the first instructions, Graphics Processor Units (GPUs) that may execute first instructions to perform one or more operations and/or functions, Digital Signal Processors (DSPs) that may execute first instructions to perform one or more operations and/or functions, XPUs, Network Processing Units (NPUs) one or more microcontrollers that may execute first instructions to perform one or more operations and/or functions and/or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and/or any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein integrated circuit/circuitry is defined as one or more semiconductor packages containing one or more circuit elements such as transistors, capacitors, inductors, resistors, current paths, diodes, etc. For example an integrated circuit may be implemented as one or more of an ASIC, an FPGA, a chip, a microchip, programmable circuitry, a semiconductor substrate coupling multiple circuit elements, a system on chip (SoC), etc.

From the foregoing, it will be appreciated that example systems, apparatus, articles of manufacture, and methods have been disclosed that enable improved cooling of IC packages in servers, and especially 2 U servers. Improved cooling is achieved with a heatsink assembly that includes a first array of fins that include overhang portions that extend over the top of DIMMs on an associated circuit board. Further, example heatsink assemblies disclosed herein include heat pipes that are thermally coupled to a heatsink base and also extend over the top of the DIMMs (e.g., within the overhanging portions of the array of fins. In some examples, the heatsink assembly also includes additional heat pipes that extend from the heatsink base to additional arrays of fins positioned upstream of the first array of fins. In some such examples, the additional heat pipes are connected to the bottom side of the heatsink base to be directly thermally coupled to an underlying IC package for enhanced thermal dissipation. Disclosed systems, apparatus, articles of manufacture, and methods are accordingly directed to one or more improvement(s) in the operation of a machine such as a computer or other electronic and/or mechanical device.

Further examples and combinations thereof include the following:

Example 1 includes a heatsink assembly comprising a base having a first lateral edge and a second lateral edge opposite the first lateral edge, first fins between the first and second lateral edges of the base, the first fins having a first height defined between first bottom edges and first top edges, the first bottom edges thermally coupled to the base, and second fins coupled to the first fins, the second fins in a region beyond the first lateral edge of the base, the second fins having a second height defined between second bottom edges and second top edges, the second height less than the first height, the second fins closer to the first top edges of the first fins than the second fins are to the first bottom edges of the first fins.

Example 2 includes any preceding clause(s) of example 1, wherein the second top edges of the second fins are at a same elevation relative to the base as the first top edges of the first fins.

Example 3 includes any preceding clause(s) of any one or more of examples 1-2, wherein lengths of the second bottom edges are less than lengths of the second top edges.

Example 4 includes any preceding clause(s) of any one or more of examples 1-3, wherein the second height is less than half the first height.

Example 5 includes any preceding clause(s) of any one or more of examples 1-4, wherein the second bottom edges of the second fins are to overhang a dual in-line memory module when the base is coupled to a circuit board carrying the dual in-line memory module.

Example 6 includes any preceding clause(s) of any one or more of examples 1-5, including a heat pipe extending through both the first fins and the second fins.

Example 7 includes any preceding clause(s) of any one or more of examples 1-6, where the end is a first end, the heat pipe including a second end thermally coupled to the base.

Example 8 includes any preceding clause(s) of any one or more of examples 1-7, wherein the heat pipe has a U-shape defined by a shoulder between first and second stems, the first stem longer than the second stem.

Example 9 includes any preceding clause(s) of any one or more of examples 1-8, wherein the first stem extends through both the first and second fins, the second stem extends across the base between the first and second lateral edges, and the shoulder is proximate the second lateral edge of the base.

Example 10 includes any preceding clause(s) of any one or more of examples 1-9, wherein the first stem extends through holes in a first portion of the first fins, and the second stem extends underneath the first bottom edges of a first portion of the first fins, perimeters of the holes extending around the first stem such that part of the first portion of the first fins is between the first and second stems.

Example 11 includes any preceding clause(s) of any one or more of examples 1-10, wherein the first stem extends through slots in a second portion of the first fins, the slots extending from the first stem to the first bottom edges of the second portion of the first fins such that there is an open space between the first stem and the second stem.

Example 12 includes any preceding clause(s) of any one or more of examples 1-11, wherein the heat pipe is a first heat pipe, the heatsink assembly including a second heat pipe thermally coupled to the base, the first heat pipe extending along a first surface of the base in a first direction transverse to the first and second lateral edges, the second heat pipe extending along a second surface of the base in a second direction transverse to the first direction, the second surface opposite the first surface.

Example 13 includes any preceding clause(s) of any one or more of examples 1-12, wherein the first surface faces towards the first fins and the second surface faces away from the first fins, a bottom surface of the second heat pipe substantially flush with the second surface.

Example 14 includes any preceding clause(s) of any one or more of examples 1-13, wherein the first heat pipe is in a first channel in the first surface and the second heat pipe is in a second channel in the second surface, the first channel intersecting the second channel to define an opening extending through the base.

Example 15 includes any preceding clause(s) of any one or more of examples 1-14, wherein the region is a first region, and the heat pipe is a first heat pipe, the heatsink assembly including third fins coupled to the first fins, the third fins in a region beyond the second lateral edge of the base, the first heat pipe spaced apart from the third fins, and a second heat pipe extending through both the first fins and the third fins such that an end of the second heat pipe extends beyond the second lateral edge of the base, the second heat pipe spaced apart from the second fins.

Example 16 includes any preceding clause(s) of any one or more of examples 1-15, wherein the base includes a width defined by the first and second lateral edges, and the first fins are distributed in series across the width.

Example 17 includes any preceding clause(s) of any one or more of examples 1-16, including a heat pipe extending beyond the first lateral edge of the base

Example 18 includes any preceding clause(s) of any one or more of examples 1-17, including a rod extending through the first fins, the second fins, and the third fins.

Example 19 includes an apparatus comprising a heatsink base, and an array of fins coupled to the heatsink base, the array of fins including a first overhanging portion, a second overhanging portion, and a central portion, the central portion between the first and second overhanging portions, the central portion having a bottom side that is coupled to the heatsink base, the overhanging portions extending outward from the central portion beyond lateral edges of the heatsink base, the overhanging portions closer to a top side of the central portion than the overhanging portions are to the bottom side.

Example 20 includes any preceding clause(s) of example 19, including a first heat pipe, a first portion of the first heat pipe extending through the first overhanging portion and the central portion, a second portion of the first heat pipe adjacent the heatsink base, and a second heat pipe, a first portion of the second heat pipe extending through the second overhanging portion and the central portion, a second portion of the second heat pipe adjacent the heatsink base.

Example 21 includes any preceding clause(s) of any one or more of examples 19-20, including a metal rod extending through the first overhanging portion, the second overhanging portion, and the central portion.

Example 22 includes a server comprising a circuit board, a socket on the circuit board to receive an integrated circuit package, first and second memory slots on the circuit board to receive respective first and second memory cards, the socket between the first and second memory slots, and a heatsink assembly to be thermally coupled to the integrated circuit package, the heatsink assembly including a first array of fins to extend over the first memory card in the first memory slot, and a second array of fins to extend over the second memory card in the second memory slot.

Example 23 includes any preceding clause(s) of example 22, wherein the heatsink assembly includes a first heat pipe shaped to extend over the first memory card, and a second heat pipe shaped to extend over the second memory card.

Example 24 includes any preceding clause(s) of any one or more of examples 22-23, wherein the heatsink assembly includes a support rod extending over the first and second memory slots through the first and second arrays of fins.

Example 25 includes any preceding clause(s) of any one or more of examples 22-24, wherein the first array of fins enable replacement of the first memory card in the first memory slot while the heatsink assembly is thermally coupled to the integrated circuit packages.

Example 26 includes any preceding clause(s) of any one or more of examples 22-25, wherein the heatsink assembly includes a base, a third array of fins, and a heat pipe extending from the base to the third array of fins, a portion of the heat pipe embedded within a channel along a bottom surface of the base, the bottom surface to be pressed against the integrated circuit package.

Example 27 includes a method comprising attaching a U-shaped heat pipe to a first section of an array of fins, a first arm of the U-shaped heat pipe extending through holes in the first section of the array of fins, a second arm of the U-shaped extending underneath bottom edges of the fins, the second arm shorter than the first arm, and attaching the U-shaped heat pipe to a heatsink base, the second arm between the heatsink base on the bottom edges of the fins.

Example 28 includes any preceding clause(s) example 27, wherein the U-shaped heat pipe includes a shoulder extending between the first and second arms, the method including attaching a second section of the array of fins to the first section, fins in the second section including an elongate slot that fits around the shoulder.

Example 29 includes any preceding clause(s) of any one or more of examples 27-28, wherein both the first and second sections of the array of fins are to be directly attached to the heatsink base, the method including attaching a third section of the array of fins to the second section of the array of fins, the third section to be spaced apart from and extend beyond a lateral edge of the heatsink base.

Example 30 includes any preceding clause(s) of any one or more of examples 27-29, including inserting a metal rod through the first and second sections of the array of fins, a portion of the metal rod to extend beyond the second section, the attaching of the third section to the second section including attaching the third section around the portion of the metal rod.

Example 31 includes any preceding clause(s) of any one or more of examples 27-30, wherein the U-shaped heat pipe extends along a first side of the heatsink base, the method including attaching a second heat pipe to the heatsink base, the second heat pipe extending along a second side of the heatsink base, the second side opposite the first side.

Example 32 includes any preceding clause(s) of any one or more of examples 27-31, including at least one of grinding or milling at least one of the second side of the heatsink base or the second heat pipe to make the heat pipe substantially flush with the second side of the heatsink base.

The following claims are hereby incorporated into this Detailed Description by this reference. Although certain example systems, apparatus, articles of manufacture, and methods have been disclosed herein, the scope of coverage of this patent is not limited thereto. On the contrary, this patent covers all systems, apparatus, articles of manufacture, and methods fairly falling within the scope of the claims of this patent.

What is claimed is:

1. A heatsink assembly comprising:
a base having a first lateral edge and a second lateral edge opposite the first lateral edge;
first fins between the first and second lateral edges of the base, the first fins having a first height defined between first bottom edges and first top edges, the first bottom edges thermally coupled to the base; and
second fins coupled to the first fins, the second fins in a region beyond the first lateral edge of the base, the second fins having a second height defined between second bottom edges and second top edges, the second height less than the first height, the second fins closer to the first top edges of the first fins than the second fins are to the first bottom edges of the first fins.

2. The heatsink assembly of claim 1, wherein the second top edges of the second fins are at a same elevation relative to the base as the first top edges of the first fins.

3. The heatsink assembly of claim 1, wherein lengths of the second bottom edges are less than lengths of the second top edges.

4. The heatsink assembly of claim 1, wherein the second bottom edges of the second fins are to overhang a dual in-line memory module when the base is coupled to a circuit board carrying the dual in-line memory module.

5. The heatsink assembly of claim 1, including a heat pipe extending through both the first fins and the second fins.

6. The heatsink assembly of claim 5, where the end is a first end, the heat pipe including a second end thermally coupled to the base.

7. The heatsink assembly of claim 5, wherein the heat pipe has a U-shape defined by a shoulder between first and second stems, the first stem longer than the second stem.

8. The heatsink assembly of claim 7, wherein the first stem extends through both the first and second fins, the second stem extends across the base between the first and second lateral edges, and the shoulder is proximate the second lateral edge of the base.

9. The heatsink assembly of claim 7, wherein the first stem extends through holes in a first portion of the first fins, and the second stem extends underneath the first bottom edges of a first portion of the first fins, perimeters of the holes extending around the first stem such that part of the first portion of the first fins is between the first and second stems.

10. The heatsink assembly of claim 9, wherein the first stem extends through slots in a second portion of the first fins, the slots extending from the first stem to the first bottom edges of the second portion of the first fins such that there is an open space between the first stem and the second stem.

11. The heatsink assembly of claim 5, wherein the heat pipe is a first heat pipe, the heatsink assembly including a second heat pipe thermally coupled to the base, the first heat pipe extending along a first surface of the base in a first direction transverse to the first and second lateral edges, the second heat pipe extending along a second surface of the base in a second direction transverse to the first direction, the second surface opposite the first surface.

12. The heatsink assembly of claim 11, wherein the first surface faces towards the first fins and the second surface faces away from the first fins, a bottom surface of the second heat pipe substantially flush with the second surface.

13. The heatsink assembly of claim 5, wherein the region is a first region, and the heat pipe is a first heat pipe, the heatsink assembly including:
third fins coupled to the first fins, the third fins in a region beyond the second lateral edge of the base, the first heat pipe spaced apart from the third fins; and
a second heat pipe extending through both the first fins and the third fins such that an end of the second heat pipe extends beyond the second lateral edge of the base, the second heat pipe spaced apart from the second fins.

14. An apparatus comprising:
a heatsink base; and
an array of fins coupled to the heatsink base, the array of fins including a first overhanging portion, a second overhanging portion, and a central portion, the central portion between the first and second overhanging portions, the central portion having a bottom side that is coupled to the heatsink base, the overhanging portions extending outward from the central portion beyond lateral edges of the heatsink base, the overhanging portions closer to a top side of the central portion than the overhanging portions are to the bottom side.

15. The apparatus of claim 14, including:
a first heat pipe, a first portion of the first heat pipe extending through the first overhanging portion and the central portion, a second portion of the first heat pipe adjacent the heatsink base; and
a second heat pipe, a first portion of the second heat pipe extending through the second overhanging portion and the central portion, a second portion of the second heat pipe adjacent the heatsink base.

16. The apparatus of claim 14, including a metal rod extending through the first overhanging portion, the second overhanging portion, and the central portion.

17. A server comprising:
a circuit board;
a socket on the circuit board to receive an integrated circuit package;
first and second memory slots on the circuit board to receive respective first and second memory cards, the socket between the first and second memory slots; and
a heatsink assembly to be thermally coupled to the integrated circuit package, the heatsink assembly including:
a first array of fins to extend over the first memory card in the first memory slot; and
a second array of fins to extend over the second memory card in the second memory slot.

18. The server of claim 17, wherein the heatsink assembly includes:
a first heat pipe shaped to extend over the first memory card; and
a second heat pipe shaped to extend over the second memory card.

19. The server of claim 17, wherein the first array of fins enable replacement of the first memory card in the first memory slot while the heatsink assembly is thermally coupled to the integrated circuit packages.

20. The server of claim 17, wherein the heatsink assembly includes:
a base;
a third array of fins; and
a heat pipe extending from the base to the third array of fins, a portion of the heat pipe embedded within a channel along a bottom surface of the base, the bottom surface to be pressed against the integrated circuit package.
